(19) United States
(12) Patent Application Publication
(10) Pub. No.: US 2010/0176374 A1
(43) Pub. Date: Jul. 15, 2010

(54) NITRIDE SEMICONDUCTOR DEVICE

(75) Inventors: Jae Woong HAN, Seoul (KR); Hee Seok PARK, Suwon (KR); Seong Suk LEE, Suwon (KR); Soo Min LEE, Seoul (KR)

Correspondence Address: MCDERMOTT WILL & EMERY LLP, 18191 VON KARMAN AVE., SUITE 500, IRVINE, CA, 92612-7108, US

(73) Assignee: SAMSUNG ELECTRO-MECHANICS CO., LTD, Suwon (KR)

(21) Appl. No.: 12/352,941

(22) Filed: Jan. 13, 2009

(51) Int. Cl. H01L 29/66

(52) U.S. Cl. 257/14; 257/E29.168

(57) ABSTRACT

A nitride semiconductor device according to an aspect of the invention may include: first and second conductive nitride semiconductor layers; and an active layer having a DH structure located between the first and second conductive nitride semiconductor layers, and including a single quantum well structure active layer having the single quantum well structure includes at least one polarization relaxation layer formed of a nitride single crystal having a higher energy band gap than the quantum well.

### BACKGROUND OF THE INVENTION

1. Field of the Invention

The present invention relates to nitride semiconductor devices, and more particularly, to a nitride semiconductor device including an active layer having a double hetero-junction (DH) structure.

2. Description of the Related Art

In general, nitride semiconductor devices have been widely used in green or blue light emitting diodes (LEDs) or laser diodes (LDs) that are provided as light sources of full-color displays, image scanners, various signal systems, and optical communication devices. The nitride semiconductor device may be provided as a light emitting device including an active layer to emit light of various colors including blue and green by recombination of holes and electrons.

Since the development of the nitride semiconductor devices, the technological advancements have been made to expand the utilization of the nitride semiconductor devices. Research has also been made on the nitride semiconductor devices serving as general lighting and vehicle light source. Particularly, in the related art, the nitride semiconductor device has been used as a component that is generally applied to a low power, low current mobile product. Recently, the use of the nitride semiconductor device has been gradually expanded to a high power, high current product. Correspondingly, there has been a desperate need for an LED structure having high efficiency at a high current density.

Luminous efficiency of the nitride semiconductor device, such as an LED, is originally determined according to recombination efficiency of electrons and holes within an active layer, that is, internal quantum efficiency.

The active layer of the nitride semiconductor device has two types of structures, that is, a single quantum well (SQW) structure having one quantum well layer (hereinafter, referred to a “DH structure active layer”) and a multi quantum well (MQW) structure having a plurality of quantum well layers each having a thickness of approximately 100 Å or less.

In general, the active layer having the multi quantum well structure has been widely used since it has more excellent luminous efficiency for the current and higher luminous output than the single quantum well structure.

As shown in a graph of FIG. 1A, it is shown in a wave function (a dotted line: electron, a solid line: hole) that the distribution of electrons and holes is determined according to a difference in mobility between the electrons and the hole, and decreases as the distance from each of the n-type and p-type nitride semiconductor layers increases. As a result, as shown in FIG. 1B, effective recombination is concentrated on the quantum well layer located at a region II adjacent to the p-type nitride semiconductor layer.

As such, an effective active region of the entire active layer having the multi quantum well structure may be reduced due to insufficient injection of carriers into a specific local area. This may case a reduction in luminous efficiency.

Therefore, in order to obtain a light emitting device having high efficiency at high power, it is desirable to use an active layer having a thick single quantum well (SQW) structure, that is, a double hetero-junction (DH) structure. In theory, even when the number of carriers increases, the DH structure without using a quantum barrier (QB) maintains constant recombination efficiency between electrons and holes by spreading the carriers into the SQW structure (refer to FIG. 2A).

However, when a nitride semiconductor device having an InGaN/GaN active layer uses a thick SQW layer, as shown in FIG. 2B, a very strong piezoelectric effect is generated to significantly reduce luminous efficiency and shorten the wavelength. Therefore, there may be no room for increasing growth temperature of the active layer.

As described above, in theory, the active layer having the SQW structure logically increases the entire recombination efficiency to thereby improve the luminous efficiency, but at the same time, the reduction in luminous efficiency and the shortened wavelength are caused by the piezoelectric effect.

### SUMMARY OF THE INVENTION

An aspect of the present invention provides a nitride semiconductor device that can ensure high efficiency at a high current density by reducing the piezoelectric effect.

According to an aspect of the present invention, there is provided a nitride semiconductor device including: first and second conductive nitride semiconductor layers; and an active layer having a DH structure located between the first and second conductive nitride semiconductor layers, and including a single quantum well structure active layer having the single quantum well structure includes at least one polarization relaxation layer formed of a nitride single crystal having a higher energy band gap than the quantum well structure.

Preferably, the active layer may have a thickness within a range of 180 to 280 Å.

Preferably, the polarization relaxation layer may have a thickness with a range of 7 to 15 Å.

The polarization relaxation layer may include a plurality of polarization relaxation layers, and the plurality of polarization relaxation layers may be arranged at regular intervals.

The interval between the polarization relaxation layers may be preferably within a range of 50 to 70 Å.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a graph illustrating a carrier wave function in an active layer of a multi quantum well structure according to the related art;

FIG. 1B is a graph illustrating an effective active region of an active layer of a multi quantum well structure according to the related art;

FIG. 2A is a schematic view illustrating a theoretical band diagram illustrating an active layer having a single quantum well structure according to the related art;

FIG. 2B is a view illustrating an actual band diagram according to piezoelectric polarization of an active layer having a single quantum well structure according to the related art;

FIG. 3 is a cross-sectional view illustrating a nitride semiconductor device having a single quantum well structure according to an exemplary embodiment of the present invention; and

FIG. 4 is a band diagram illustrating an active layer region of the nitride semiconductor device illustrated in FIG. 3.

### DETAILED DESCRIPTION OF THE PREFERRED EMBODIMENT

Exemplary embodiments of the present invention will now be described in detail with reference to the accompanying drawings.

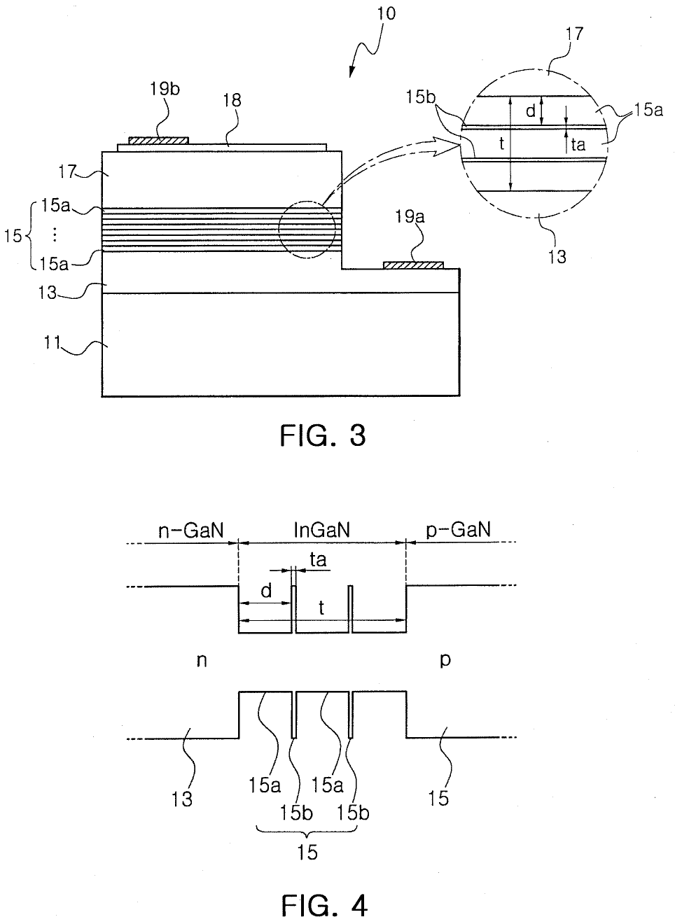

FIG. 3 is a cross-sectional view illustrating a nitride semiconductor device having a single quantum well structure according to an exemplary embodiment of the invention.

As shown in FIG. 3, a nitride semiconductor device 10 includes a substrate 11, an n-type nitride semiconductor layer 13, an active layer 15, and a p-type nitride semiconductor layer 17. The n-type nitride semiconductor layer 13 is mesa-etched to expose a top surface thereof, and an n-type electrode 19a is formed on the exposed top surface of the n-type nitride semiconductor layer 13. Further, a transparent electrode layer 18 is formed on the top surface of the p-type nitride semiconductor layer 17, and a p-type electrode 19b is formed on the transparent electrode layer 18.

In this embodiment, a horizontal nitride semiconductor light emitting device having both electrodes 19a and 19b formed on the same plane is exemplified. However, the invention is not limited thereto, and can be applied to a vertical nitride semiconductor light emitting device, which may be easily understood by a person skill in the art.

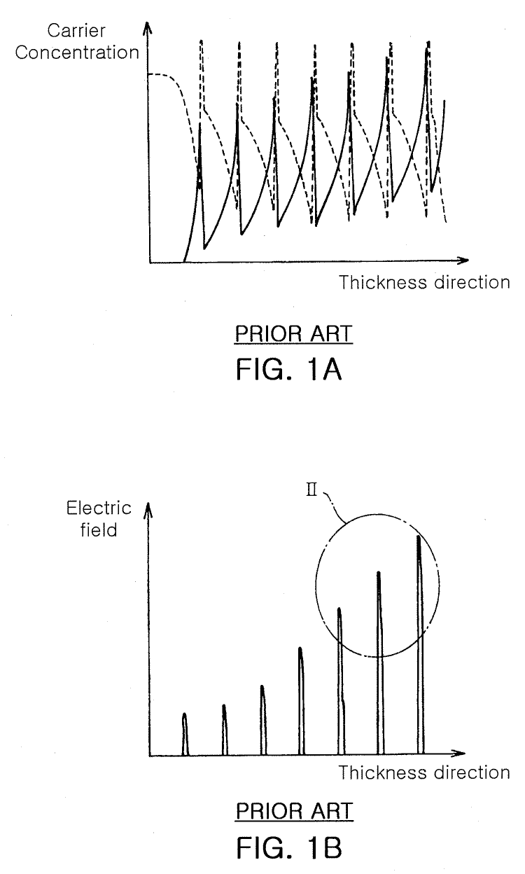

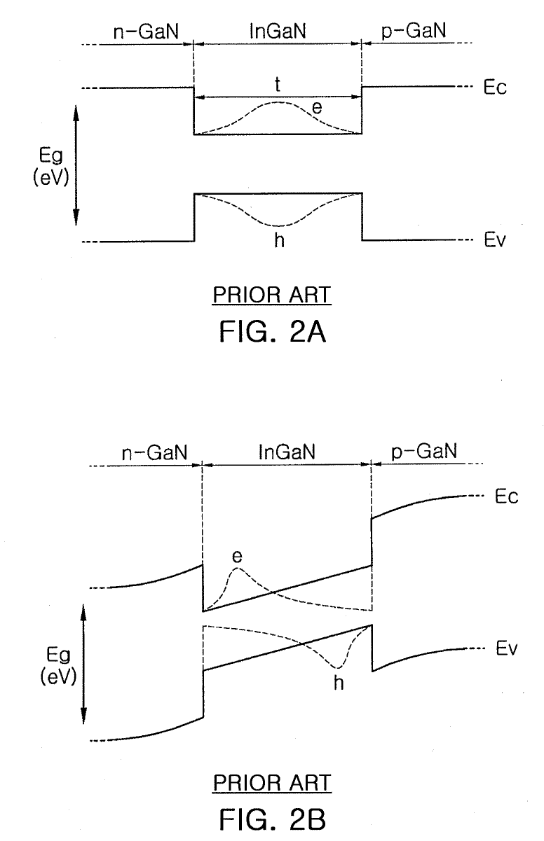

As shown in FIG. 1, the active layer 15 has a single quantum well structure, that is, a double hetero-junction (DH) structure. Further, the active layer 15 includes polarization relaxation layers 15b to reduce the piezoelectric effect caused by a large thickness of the single quantum well structure.

The polarization relaxation layer 15b may be a nitride semiconductor layer having a higher energy band gap than the quantum well structure 15a. For example, when the quantum well structure is formed of Inₓ₁Ga₁₋ₓ₁N, the polarization relaxation layer 15b may be formed of GaN or Inₓ₂Ga₁₋ₓ₂N (X1>X2) that has a relatively low In content.

Further, the polarization relaxation layer 15b is a very thin film as compared with a general quantum barrier layer (for example, approximately 30 to 100 Å). Specifically, the polarization relaxation layer 15b, used in this embodiment, has a very slight thickness so that the electrons and the holes injected into the active layer 15 can tunnel through the polarization relaxation layer 15b without taking it as a quantum barrier.

For this operation, a thickness tₐ of the polarization relaxation layer 15b is preferably 15 Å or less. Further, the thickness tₐ of the polarization relaxation layer 15b is preferably 7 Å or more to obtain sufficient polarization relaxation.

In this embodiment, there are two polarization relaxation layers 15b. The quantum well structure 15a is structurally divided into three regions by the two polarization relaxation layers 15b. However, as described above, in quantum mechanics, since the polarization relaxation layer 15b does not serve as the quantum barrier since it has a very slight thickness, the polarization relaxation layer 15b may perform a similar operation as the single quantum well structure. Carriers injected into the active layer 15 can perform the same movement within a thickness range of the polarization relaxation layer 15b as in the single quantum well structure.

In this embodiment, a plurality of polarization relaxation layers are exemplified. However, even when one polarization relaxation layer is used, a similar effect can be expected according to the thickness of the single quantum well structure, which is obvious to a person skilled in the art.

A thickness t of the active layer 15 having the DH structure, used in this embodiment, may have a thickness of 100 to 250 Å. When the thickness t is less than 180 Å, it is difficult to maintain high recombination efficiency over the entire area of the active layer 15 having the single quantum well structure. When the thickness t is more than 280 Å, it is difficult to reduce the polarization and In segregation may occurs in the well structure, resulting in deteriorating the crystal quality.

When the plurality of polarization relaxation layers 15b are used like this embodiment, it is preferable the plurality of polarization relaxation layers 15b are spaced at regular intervals d. As sustaining InGaN crystal quality, to minimize Auger non-radiative recombination, the interval d between the polarization relaxation layers 15b is preferably within a range of 50 to 70 Å.

FIG. 4 is a band diagram illustrating an active layer region of the nitride semiconductor device illustrated in FIG. 3. That is, the active layer region, shown in FIG. 4, can be understood as the active layer 15, shown in FIG. 3, and its circumference. Here, a vertical axis indicates absolute size eV of an energy band gap, and a horizontal axis indicates a perpendicular distance from an n-type nitride semiconductor layer to a p-type nitride semiconductor layer.

In this diagram, the n-type and p-type nitride semiconductor layers 13 and 17 formed of n-type and p-type GaN, respectively, are exemplified. Further, the active layer 15 having a single quantum well structure formed of InGaN and located between the n-type nitride semiconductor layer 13 and the p-type nitride semiconductor layer 17 is exemplified.

As shown in FIG. 4A, the quantum well structure of the active layer 15 is divided into three regions 15a by the polarization relaxation layers 15b that are arranged at regular intervals. The polarization relaxation layer 15b has a higher energy band gap than the quantum well structure. Here, the polarization relaxation layer 15b formed of GaN is exemplified.

As described above, the thickness of the polarization relaxation layer 15b is small enough for the carriers to tunnel therethrough. That is, even when the polarization relaxation layer 15b is formed of a semiconductor material having the same composition as the general quantum barrier layer, the polarization relaxation layer 15b does not serve as the quantum barrier since it has the very slight thickness tₐ, but may be used to obtain polarization relaxation.

Therefore, even though the active layer 15 having the single quantum structure has the large thickness t, since the actual size causing the polarization action is limited to the intervals between the polarization relaxation layers, the entire influence caused by the piezoelectric effect can be significantly reduced.

As such, the piezoelectric effect can be reduced by appropriately using polarization relaxation layers in the single quantum well structure. As a result, blue-shifting of a green wavelength that may be caused in a light emitting device that operates at high power is prevented to thereby provide wavelength stabilization.

As set forth above, according to an exemplary embodiment of the invention, while an active layer having a single quantum well structure that can prevent a local reduction in carrier injection efficiency is used, polarization caused by the piezoelectric effect can be prevented by introduction of at least one polarization relaxation layer to a thick quantum well layer. Since output at a high current density can be significantly increased, the invention can be advantageously applied to a high-output nitride semiconductor device. Further, blue-shifting of a light emitting device emitting light of a green wavelength, which is a problem of the thick quantum well structure, is prevented to thereby obtain wavelength stabilization.

While the present invention has been shown and described in connection with the exemplary embodiments, it will be apparent to those skilled in the art that modifications and variations can be made without departing from the spirit and scope of the invention as defined by the appended claims.

1. A nitride semiconductor device comprising:
first and second conductive nitride semiconductor layers; and
an active layer having a DH structure located between the first and second conductive nitride semiconductor layers, and including a single quantum well,
wherein the active layer having the single quantum well includes at least one polarization relaxation layer formed of a nitride single crystal having a higher energy band gap than the quantum well,
wherein the at least one polarization relaxation layer divides the single quantum well into at least two regions and is in contact with the at least two regions, and
wherein the polarization relaxation layer has a thickness within a range of 7 Å to 15 Å.

2. The nitride semiconductor device of claim 1, wherein the active layer has a thickness within a range of 180 to 280 Å.

3. (canceled)

4. The nitride semiconductor device of claim 1, wherein the active layer comprises a plurality of polarization relaxation layers, and the plurality of polarization relaxation layers are arranged at regular intervals.

5. The nitride semiconductor device of claim 4, wherein the interval between the polarization relaxation layers is 50 to 70 Å.
